(19) United States
(12) Patent Application Publication
(10) Pub. No.: US 2025/0080449 A1
(43) Pub. Date: Mar. 6, 2025

(54) ETHERNET PHYSICAL-LAYER TRANSCEIVER USING DIFFERENT PHASE COMBINATIONS OF TRANSMITTER CLOCK AND RECEIVER CLOCK TO OBTAIN SAMPLES FOR CHANNEL CHARACTERISTIC ANALYSIS AND RELATED CHANNEL CHARACTERISTIC ANALYSIS METHOD

(71) Applicant: Airoha Technology Corp., Hsinchu City (TW)

(72) Inventors: Yi-Ching Chen, New Taipei City (TW); Chia-Hsing Hsu, New Taipei City (TW)

(73) Assignee: Airoha Technology Corp., Hsinchu City (TW)

(21) Appl. No.: 18/796,274

(22) Filed: Aug. 6, 2024

Related U.S. Application Data
(60) Provisional application No. 63/535,065, filed on Aug. 28, 2023.
(60) Provisional application No. 63/545,364, filed on Oct. 24, 2023.

(51) Int. Cl. H04L 43/50; G01R 31/11; H04L 7/02

(52) U.S. Cl. CPC H04L 43/50; G01R 31/11; H04L 7/02

(57) ABSTRACT

An Ethernet physical-layer transceiver includes a control circuit and a processing circuit. The control circuit sequentially employs a plurality of different phase combinations of a transmitter clock and a receiver clock for transmission and reception of data over a cable, and obtains a plurality of sets of samples from the cable under the plurality of different phase combinations of the transmitter clock and the receiver clock, respectively. The processing circuit performs channel characteristic analysis according to the plurality of sets of samples provided by the control circuit.

### CROSS REFERENCE TO RELATED APPLICATIONS

This application claims the benefit of U.S. Provisional Application No. 63/535,065, filed on Aug. 28, 2023. Further, this application claims the benefit of U.S. Provisional Application No. 63/545,364, filed on Oct. 24, 2023. The contents of these applications are incorporated herein by reference.

### BACKGROUND OF THE INVENTION

### 1. Field of the Invention

The present invention relates to an Ethernet physical-layer (PHY) transceiver design, and more particularly, to an Ethernet PHY transceiver using different phase combinations of a transmitter clock and a receiver clock to obtain samples for channel characteristic analysis and a characteristic analysis method.

### 2. Description of the Prior Art

The time domain reflectometry (TDR) function aims at determining the characteristic of an electrical line such as a network cable. As long as an integrated circuit (IC) has capability of transmitting an incident signal onto a medium and observing a reflected signal from the medium, it can provide channel information such as reflection ratio or impulse response. For example, post-processing of reflection ratios may provide certain channel information, including return loss, cable length, cable quality, termination type, etc. Based on IEEE 802.3 1G/2.5G/5G/10G specification, the hardware design of the physical layer observes the reflection by sending and receiving signals according to an operating sampling rate (which is the same as the baud rate) under a normal mode. However, regarding the TDR operation, the operating sampling rate at the normal mode is not sufficient to capture the channel response detailedly. That is, some transients may not be captured at the normal mode, which highly causes the misinterpretation and instability when conducting post-processing of reflection ratios for cable length calculation and termination detection. Therefore, proposing an Ethernet PHY transceiver that can effectively perform cable length calculation and termination detection is a critical task.

### SUMMARY OF THE INVENTION

One of the objectives of the claimed invention is to provide an Ethernet PHY transceiver using different phase combinations of a transmitter clock and a receiver clock to obtain samples for channel characteristic analysis and a related channel characteristic analysis method.

According to a first aspect of the present invention, an exemplary Ethernet physical-layer transceiver is disclosed. The exemplary Ethernet physical-layer transceiver includes a control circuit and a processing circuit. The control circuit is arranged to sequentially employ a plurality of different phase combinations of a transmitter clock and a receiver clock for transmission and reception of data over a cable, and obtain a plurality of sets of samples from the cable under the plurality of different phase combinations of the transmitter clock and the receiver clock, respectively. The processing circuit is arranged to perform channel characteristic analysis according to the plurality of sets of samples provided by the control circuit.

According to a second aspect of the present invention, an exemplary channel characteristic analysis method is disclosed. The exemplary channel characteristic analysis method includes: sequentially employing a plurality of different phase combinations of a transmitter clock and a receiver clock of an Ethernet physical-layer transceiver for transmission and reception of data over a cable; obtaining a plurality of sets of samples from the cable under the plurality of different phase combinations of the transmitter clock and the receiver clock, respectively; and performing channel characteristic analysis according to the plurality of sets of samples.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a diagram illustrating an Ethernet physical-layer transceiver that: supports the proposed high resolution mode according to an embodiment of the present invention.

FIG. 2 is a diagram illustrating a control circuit according to an embodiment of the present invention.

FIG. 3 is a flowchart illustrating a method of performing data collection at the high resolution mode by shifting phases in a regular sequence according to an embodiment.

FIG. 4 is a diagram illustrating samples collected from different phases at the high resolution mode according to an embodiment of the present invention.

FIG. 5 is a diagram illustrating a pseudo random binary sequence generator according to an embodiment of the present invention.

FIG. 6 is a flowchart illustrating a method of performing data collection at the high resolution mode by shifting phases in an irregular sequence according to an embodiment.

FIG. 7 is a diagram illustrating data samples obtained at different phases and a high resolution profile derived from interpolation according to an embodiment of the present invention.

### DETAILED DESCRIPTION

Certain terms are used throughout the following description and claims, which refer to particular components. As one skilled in the art will appreciate, electronic equipment manufacturers may refer to a component by different names. This document does not intend to distinguish between components that differ in name but not in function. In the following description and in the claims, the terms “include” and “comprise” are used in an open-ended fashion, and thus should be interpreted to mean “include, but not limited to . . . ”. Also, the term “couple” is intended to mean either an indirect or direct electrical connection. Accordingly, if one device is coupled to another device, that connection may be through a direct electrical connection, or through an indirect electrical connection via other devices and connections.

To address the misinterpretation and instability issues in a normal mode, one conventional solution may use a higher sampling rate at the expense of higher hardware cost. Thus, there is a need for an innovative cost-efficient solution that can overcome the insufficient sampling rate issue without increasing the sampling rate.

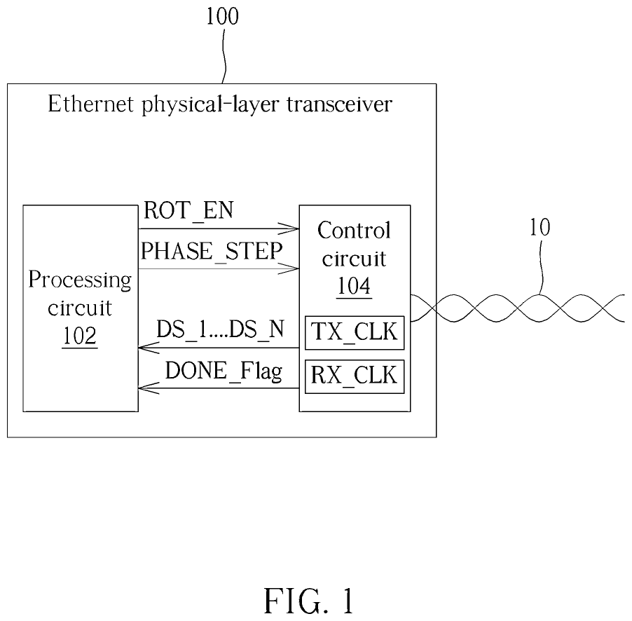

FIG. 1 is a diagram illustrating an Ethernet physical-layer (PHY) transceiver that supports the proposed high resolution mode according to an embodiment of the present invention. For example, the Ethernet PHY transceiver 100 may be a 1000 BASE-T transceiver, a 2.5G BASE-T transceiver, a 5G BASE-T transceiver or a 10G BASE-T transceiver, and may support a hybrid mode for transmission and reception of data over a cable 10. As shown in FIG. 1, the Ethernet PHY transceiver 100 includes a processing circuit 102 and a control circuit 104. It should be noted that only the components pertinent to the present invention are shown in FIG. 1. In practice, the Ethernet PHY transceiver 100 may include additional components for other functions.

The processing circuit 102 may be implemented by a microcontroller unit (MCU). In this embodiment, the processing circuit 102 is arranged to manage operations of the high resolution mode. For example, the processing circuit 102 generates a plurality of control signals ROT_EN and PHASE STEP to the control circuit 104, where the control signal ROT_EN may control enabling/disabling of a function of altering the relative sampling position of a transmitter clock TX_CLK and a receiver clock RX_CLK, and the control signal PHASE_STEP may control a setting of the relative sampling position of the transmitter clock TX_CLK and the receiver clock RX_CLK.

In response to the control signals ROT_EN and PHASE_STEP generated from the processing circuit (e.g., MCU) 102, the control circuit 104 may enable the high resolution mode proposed by the present invention, and may sequentially employ a plurality of different phase combinations of the transmitter clock TX_CLK and the receiver clock RX_CLK for transmission and reception of data over the cable 10, and obtain a plurality of sets of samples DS_1-DS_N (N≥2) from the cable 10 under the different phase combinations of the transmitter clock TX_CLK and the receiver clock RX_CLK, respectively. For example, an incident signal is transmitted to the cable 10 according to the transmitter clock TX_CLK, and a reflected signal (i.e., reflection of the incident signal) is received/sampled from the cable 10 according to the receiver clock RX_CLK. In this embodiment, one set of sample DS_i (1≤i<N) is obtained from the cable 10 when the transmitter clock TX_CLK and the receiver clock RX_CLK have an i^{th} phase combination that corresponds to an i^{th} phase difference PDᵢ, and the next set of sample DS_i+1 (i+1≤N) is obtained from the cable 10 when the transmitter clock TX_CLK and the receiver clock RX_CLK have an (i+1)th phase combination that corresponds to an (i+1)^{th} phase difference PDᵢ₊₁ (PDᵢ₊₁≠PDᵢ). For example, if a phase of one of the transmitter clock TX_CLK and the receiver clock RX_CLK is fixed, the phase difference (i.e., relative sampling position of the transmitter clock TX_CLK and the receiver clock RX_CLK) can be easily adjusted by altering a phase of the other of the transmitter clock TX_CLK and the receiver clock RX_CLK.

In some embodiments of the present invention, a clock rate of each of the transmitter clock TX_CLK and the receiver clock RX_CLK is equal to the normal-mode operating clock rate (i.e., baud rate) of the Ethernet PHY transceiver 100. For example, when the Ethernet PHY transceiver 100 is a 1000 BASE-T transceiver, the baud rate is 125 MHz, and the clock rate of each of the transmitter clock TX_CLK and the receiver clock RX_CLK used at the high resolution mode is equal to 125 MHz. Hence, the proposed high resolution mode can be a cost-efficient solution which overcomes the insufficient sampling rate issue by increasing the number of samples (i.e., the number of times of sampling per unit interval (UI)) without increasing the sampling rate. Specifically, under a condition that the sampling rate is not increased, the number of samples obtained at the high resolution mode is increased by altering the relative sampling position of the transmitter clock TX_CLK and the receiver clock RX_CLK several times during one UI (i.e., symbol duration time).

Different phase combinations of the transmitter clock TX_CLK and the receiver clock RX_CLK are properly configured to ensure different phase differences between the transmitter clock TX_CLK and the receiver clock RX_CLK, where each phase difference defines one relative sampling position of the transmitter clock TX_CLK and the receiver clock RX_CLK. In this way, multiple samples at different phase differences within each UI (e.g., 8 ns for 1000 BASE-T) can be captured by the receiver for follow-up channel characteristic analysis at the processing circuit 102.

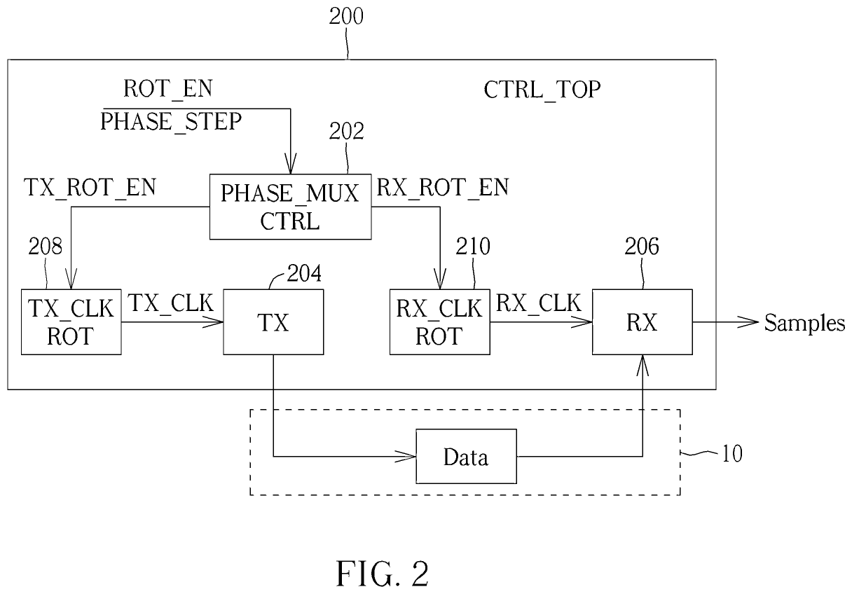

FIG. 2 is a diagram illustrating a control circuit according to an embodiment of the present invention. The control circuit 104 shown in FIG. 1 may be implemented using the control circuit (labeled by “CTRL_TOP”) 200 shown in FIG. 2. In this embodiment, the control circuit 200 may include a phase multiplexer control circuit (labeled by “PHASE_MUX CTRL”) 202, a transmitter circuit (labeled by “TX”) 204, a receiver circuit (labeled by “RX”) 206, a transmitter clock rotation circuit (labeled by “TX_CLK ROT”) 208, and a receiver clock rotation circuit (labeled by “RX_CLK ROT”) 210, where the transmitter circuit 204 is clocked by the transmitter clock TX_CLK to perform transmission of data (e.g., incident signal for TDR test) over the cable 10, and the receiver circuit 206 is clocked by the receiver clock RX_CLK to perform reception of data (e.g., reflected signal for TDR test) over the cable 10. The control circuit 200 sequentially employs different phase combinations of the transmitter clock TX_CLK and the receiver clock RX_CLK for transmission and reception of data over the cable 10. The required phase difference (i.e., relative sampling position) may be set by shifting one or both of a phase of the transmitter clock TX_CLK and a phase of the receiver clock RX_CLK, depending upon actual design considerations.

In a first phase rotation design, the phase of the receiver clock RX_CLK remains unchanged, while the phase of the transmitter clock TX_CLK is shifted to different values one by one. In response to the control signal ROT_EN, the phase multiplexer control circuit 202 generates a control signal TX ROT_EN (TX_ROT_EN=1) to enable the transmitter clock rotation circuit 208, and generates a control signal RX_ROT_EN (RX_ROT_EN=0) to disable the receiver clock rotation circuit 210. Hence, different phase combinations of the transmitter clock TX_CLK and the receiver clock RX_CLK include a combination of a first phase of the transmitter clock TX_CLK and a fixed phase of the receiver clock RX_CLK, and a combination of a second phase of the transmitter clock TX_CLK and the fixed phase of the receiver clock RX_CLK, where the second phase of the transmitter clock TX_CLK is different from the first phase of the transmitter clock TX_CLK. Specifically, the phase difference (i.e., relative sampling position) is adjusted by solely shifting the phase of the transmitter clock TX_CLK.

In a second phase rotation design, the phase of the transmitter clock TX_CLK remains unchanged, while the phase of the receiver clock RX_CLK is shifted to different values one by one. In response to the control signal ROT_EN, the phase multiplexer control circuit 202 generates the control signal TX_ROT_EN (TX_ROT_EN=0) to disable the transmitter clock rotation circuit 208, and generates the control signal RX_ROT_EN (RX_ROT_EN=1) to enable the receiver clock rotation circuit 210. Hence, different phase combinations of the transmitter clock TX_CLK and the receiver clock RX_CLK include a combination of a first phase of the receiver clock RX_CLK and a fixed phase of the transmitter clock TX_CLK, and a combination of a second phase of the receiver clock RX_CLK and the fixed phase of the transmitter clock TX_CLK, where the second phase of the receiver clock RX_CLK is different from the first phase of the receiver clock RX_CLK. Specifically, the phase difference (i.e., relative sampling position) is adjusted by solely shifting the phase of the receiver clock RX_CLK.

In a third phase rotation design, the phase of the transmitter clock TX_CLK is shifted to different values one by one, while the phase of the receiver clock RX_CLK is also shifted to different values one by one. In response to the control signal ROT_EN, the phase multiplexer control circuit 202 generates the control signal TX_ROT_EN (TX_ROT_EN=1) to enable the transmitter clock rotation circuit 208, and generates the control signal RX_ROT_EN (RX_ROT_EN=1) to enable the receiver clock rotation circuit 210. Hence, different phase combinations of the transmitter clock TX_CLK and the receiver clock RX_CLK include a combination of a first phase of the transmitter clock TX_CLK and a first phase of the receiver clock RX_CLK, and a combination of a second phase of the transmitter clock TX_CLK and a second phase of the receiver clock RX_CLK, where the second phase of the transmitter clock TX_CLK is different from the first phase of the transmitter clock TX_CLK, the second phase of the receiver clock RX_CLK is different from the first phase of the receiver clock RX_CLK, and a difference between the first phase and the second phase of the transmitter clock TX_CLK is different from a difference between the first phase and the second phase of the receiver clock RX_CLK. Specifically, the phase difference (i.e., relative sampling position) is adjusted by jointly shifting the phase of the receiver clock RX_CLK and the phase of the transmitter clock TX_CLK.

In some embodiments of the present invention, the phase of the transmitter clock TX_CLK/receiver clock RX_CLK may be shifted in a regular manner such as a sequential manner. Hence, different phase combinations of the transmitter clock TX_CLK and the receiver clock RX_CLK that are sequentially employed by the control circuit 200 correspond to different phase differences between the transmitter clock TX_CLK and the receiver clock RX_CLK, and the different phase differences are a monotonically-increasing sequence a or monotonically-decreasing sequence.

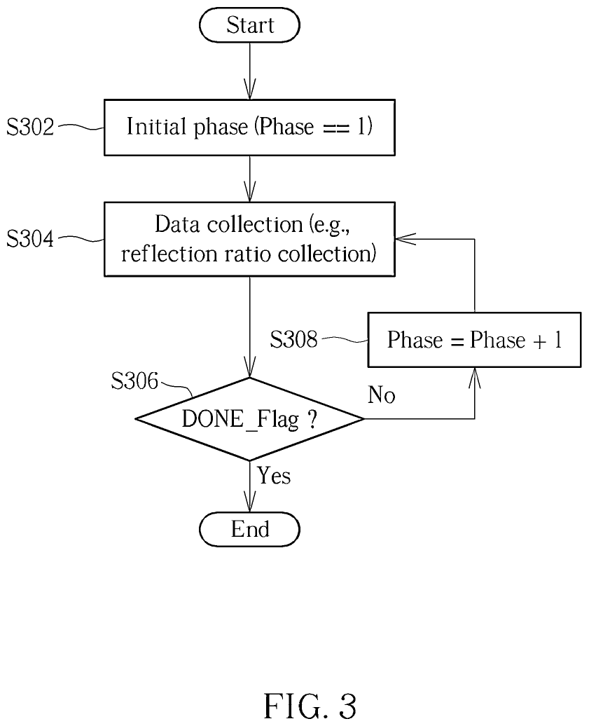

FIG. 3 is a flowchart illustrating a method of performing data collection at the high resolution mode by shifting phases in a regular sequence (e.g., sequential sequence) according to an embodiment. Suppose that one UI (i.e., symbol duration time) may be evenly (or unevenly) divided into N (e.g., N=8) partitions according to N (e.g., n=8) phases PH_1, PH_2, . . . , PH_N, where PH_j<PH_j+1, and j={1, 2, . . . , N−1}. For better comprehension, it is assumed that the aforementioned second phase rotation design is employed by the control circuit 200. A person skilled on the art should readily appreciate that a regular sequence can also be employed by aforementioned first and third phase rotation designs.

At step S302, the receiver clock rotation circuit 210 sets the phase of the receiver clock RX_CLK by an initial phase (e.g., PH_1). At step S304, the receiver circuit 206 performs sampling upon the signal (e.g., reflected signal) received from the cable 10 according to the receiver clock RX_CLK, and generates a set of samples (e.g., DS_1) for the current phase setting of the receiver clock RX_CLK. Regarding the TDR test, samples (which include reflection ratios) are collected by the receiver circuit 206 according to the current phase setting PH_1 of the receiver clock RX_CLK. At step S306, the phase multiplexer control circuit 202 checks if all phases PH_1-PH_N have been sequentially selected. If the current phase is not the last phase (e.g., PH_N) yet, the flow proceeds with step S308. At step S308, the receiver clock rotation circuit 210 shifts the phase of the receiver clock RX_CLK to a next phase (e.g., PH 2). Next, the receiver circuit 206 performs sampling upon the signal received from the cable 10 according to the receiver clock RX_CLK, and generates a set of samples (e.g., DS_2) for the current phase setting of the receiver clock RX_CLK. Regarding the TDR test, samples (e.g., reflection ratios) are collected by the receiver circuit 206 according to the current phase setting PH 2 of the receiver clock RX_CLK. Step S308 does not stop shifting the phase of the receiver clock RX_CLK until all phases PH_1-PH_N have been sequentially selected by the phase multiplexer control circuit 202 during the data collection process (e.g., reflection ratio collection for TDR test).

If the current phase is the last phase (e.g., PH_N), the control circuit 200 enables a flag DONE Flag (DONE Flag=1) to inform a processing circuit (e.g., processing circuit 102) of an end of the data collection process. After the data collection process is done, the processing circuit (e.g., processing circuit 102) performs channel characteristic analysis according to multiple sets of samples DS_1-DS_N provided by the control circuit 200. For example, the channel characteristic analysis may include a TDR test, and multiple sets of samples DS_1-DS_N may include reflection ratios. Hence, post-processing of the reflection ratios can provide channel information, including return loss, cable length, cable quality, termination type, etc.

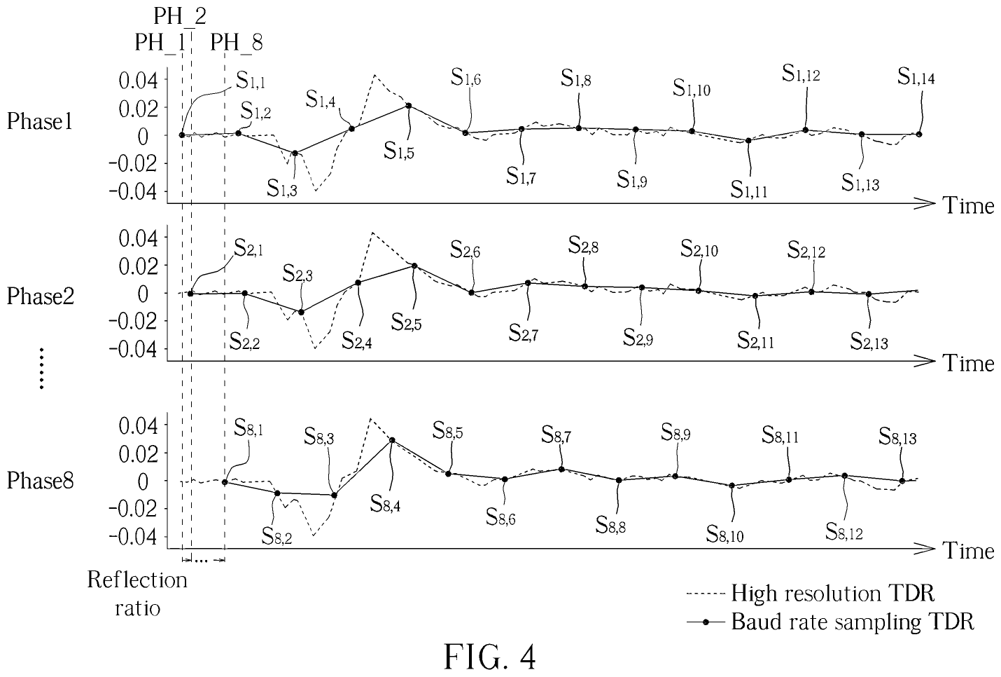

FIG. 4 is a diagram illustrating samples collected from different phases at the high resolution mode according to an embodiment of the present invention. For better comprehension of technical features of the present invention, it is assumed that 8 (N=8) phases of the receiver clock RX_CLK are used by the second phase rotation design. When the phase of the receiver clock RX_CLK is set by PH_1, consecutive samples (e.g., reflection ratios) S_{1,1}, S_{1,2}, S_{1,3}, S_{1,4}, S_{1,5}, S_{1,6}, S_{1,7}, S_{1,8}, S_{1,9}, S_{1,10}, S_{1,11}, S_{1,12}, S_{1,13}, S_{1,14} are obtained by the receiver circuit 206 according to periodic sampling timing defined by the phase PH_1 of the receiver clock RX_CLK. When the phase of the receiver clock RX_CLK is set by PH 2, consecutive samples (e.g., reflection ratios) S_{2,1}, S_{2,2}, S_{2,3}, S_{2,4}, S_{2,5}, S_{2,6}, S_{2,7}, S_{2,8}, S_{2,9}, S_{2,10}, S_{2,11}, S_{2,12}, S_{2,13} are obtained by the receiver circuit 206 according to periodic sampling timing defined by the phase PH_2 of the receiver clock RX_CLK. When the phase of the receiver clock RX_CLK is set by PH_8, consecutive samples (e.g., reflection ratios) S_{8,1}, S_{8,2}, S_{8,3}, S_{8,4}, S_{8,5}, S_{8,6}, S_{8,7}, S_{8,8}, S_{8,9}, S_{8,10}, S_{8,11}, S_{8,12}, S_{8,13} are obtained by the receiver circuit 206 according to periodic sampling timing defined by the phase PH_8 of the receiver clock RX_CLK. There are 8 samples collected at different sampling positions within one UI by using 8 phases of the receiver clock RX_CLK that has a clock rate the same as the normal-mode operating clock rate (baud rate).

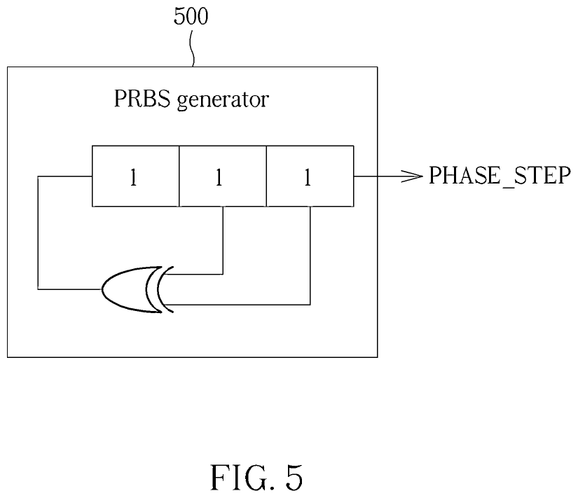

Alternatively, the phase of the transmitter clock TX_CLK (or receiver clock RX_CLK) may be shifted in an irregular manner such as a random manner. Hence, different phase combinations of the transmitter clock TX_CLK and the receiver clock RX_CLK that are sequentially employed by the control circuit 200 correspond to different phase differences between the transmitter clock TX_CLK and the receiver clock RX_CLK, and the different phase differences are not a monotonically-increasing sequence or a monotonically-decreasing sequence. In some embodiments of the present invention, the different phase differences may be a random sequence under control of the processing circuit 102. For example, the processing circuit 102 shown in FIG. 1 may be implemented by an MCU having a pseudo random binary sequence (PRBS) generator 500 shown in FIG. 5. The PRBS generator 500 is arranged to create a pseudo random sequence as the control signal PHASE_STEP, and output the control signal PHASE_STEP (which is indicative of the pseudo random sequence) to the control circuit 104 (which may be implemented using the control circuit 200 shown in FIG. 2). Hence, different phase differences between the transmitter clock TX_CLK and the receiver clock RX_CLK are set by the control circuit 104/200 in response to the pseudo random sequence provided by the processing circuit 102.

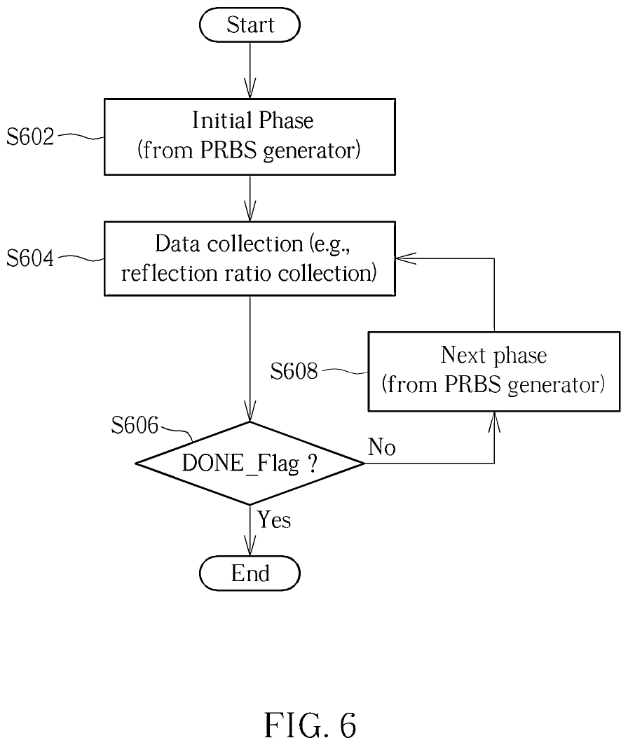

FIG. 6 is a flowchart illustrating a method of performing data collection at the high resolution mode by shifting phases in an irregular sequence (e.g., random sequence) according to an embodiment. Suppose that one UI (i.e., symbol duration time) is evenly (or unevenly) divided into 8 (N=8) partitions according to 8 (N=8) phases PH_1, PH_2, . . . , PH_8, where PH i<PH i+1. For better comprehension, it is assumed that the aforementioned second phase rotation design is employed by the control circuit 200. A person skilled on the art should readily appreciate that an irregular sequence can also be employed by aforementioned first and third phase rotation designs. Taking the PRBS generator 500 shown in FIG. 5 as an example, its pseudo random sequence may be [7→6 →4→1→2→5→3]. At step S602, the receiver clock rotation circuit 210 sets the phase of the receiver clock RX_CLK by an initial phase (e.g., PH_7) as indicated by the pseudo random sequence generated from PRBS generator 500. At step S604, the receiver circuit 206 performs sampling upon the signal (e.g., reflected signal) received from the cable 10 according to the receiver clock RX_CLK, and generates a set of samples (e.g., DS_7) for the current phase setting of the receiver clock RX_CLK. Regarding the TDR test, samples (e.g., reflection ratios) are collected by the receiver circuit 206 according to the current phase setting PH_7 of the receiver clock RX_CLK. At step S606, the phase multiplexer control circuit 202 checks if one cycle of the pseudo random sequence is completed (i.e., the current phase is the last phase PH_3 of the pseudo random sequence). If the current phase is not the last phase PH_3 of the pseudo random sequence yet, the flow proceeds with step S608. At step S608, the receiver clock rotation circuit 210 shifts the phase of the receiver clock RX_CLK to a next phase (e.g., PH_6) as indicated by the pseudo random sequence generated from PRBS generator 500. Next, the receiver circuit 206 performs sampling upon the signal (e.g., reflected signal) received from the cable 10 according to the receiver clock RX_CLK, and generates a set of samples (e.g., DS_6) for the current phase setting of the receiver clock RX_CLK. Regarding the TDR test, samples (e.g., reflection ratios) are collected by the receiver circuit 206 according to the current phase setting PH_6 of the receiver clock RX_CLK. Step S₆₀₈ does not stop shifting the phase of the receiver clock RX_CLK until one cycle of the pseudo random sequence is completed (i.e., the current phase is the last phase PH_3 of the pseudo random sequence).

If one cycle of the pseudo random sequence is completed (i.e., the current phase is the last phase PH_3 of the pseudo random sequence), the control circuit 200 enables a flag DONE Flag (DONE Flag=1) to inform a processing circuit (e.g., processing circuit 102) of an end of the data collection process. After the data collection process is done, the processing circuit (e.g., processing circuit 102) performs channel characteristic analysis according to multiple sets of samples DS_1-DS_N provided by the control circuit 200. For example, the channel characteristic analysis may include a TDR test, and multiple sets of samples DS_1-DS_N may include reflection ratios. Hence, post-processing of the reflection ratios can provide channel information, including return loss, cable length, cable quality, termination type, etc.

As mentioned above, the processing circuit 102 obtains multiple sets of samples DS_1-DS_N, and performs channel characteristic analysis according to the multiple sets of samples DS_1-DS_N. These sets of samples DS_1-DS_N are obtained from sampling the signal received from the cable 10 under the same normal-mode sampling rate (baud rate) but different phases. The processing circuit 102 can re-construct a sampling result of the high resolution mode by jointly considering these sets of samples DS_1-DS_N. For example, these sets of samples DS_1-DS_N can be combined to re-construct the sampling result of the high resolution mode. For example, when these sets of samples DS_1-DS_N are used for TDR test, a high resolution profile can be derived from interpolation.

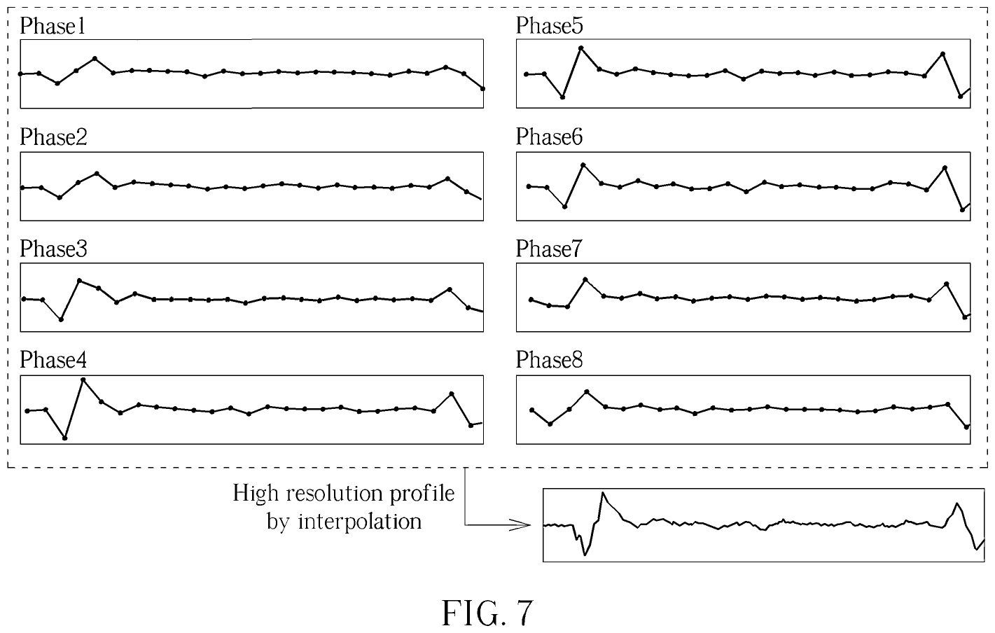

FIG. 7 is a diagram illustrating data samples obtained at different phases and a high resolution profile derived from interpolation according to an embodiment of the present invention. Compared to the profile of reflection ratios at the normal mode which is one of 8 phases at the high resolution mode, the high resolution profile of reflection ratios can indicate more channel effect phenomena and transients. Specifically, under the normal mode, the sampling rate is identical to an operating clock rate (baud rate), and the resolution of one sample can be calculated by multiplying velocity and sample time (i.e., symbol duration time). On the contrary, the sampling rate at the proposed high resolution mode is the same as the normal mode but the sampling phase is altered with time. That is, more samples obtained in one UI can increase the resolution. Therefore, more information can be observed by different sampling phases. For example, the sample time of 1000 BASE-T is 8 ns. The resolution of one sample can be calculated by multiplying velocity and sample time. The transmitted velocity in copper is ⅔ light speed (3×108 m/s). Moreover, the signal observed by the PHY circuit is the reflected signal so that the transmission distance of the signal is two times as large as the cable length. Therefore, the resolution of a tap is 0.8m. Since the number of times of sampling per UI at the high resolution mode is higher than that of the normal mode, the resolution of a tap at the high resolution mode is smaller than 0.8m. Thus, more information can be observed by more sampling phases that are intentionally created by the proposed high resolution mode.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. An Ethernet physical-layer (PHY) transceiver comprising:
a control circuit, arranged to sequentially employ a plurality of different phase combinations of a transmitter clock and a receiver clock for transmission and reception of data over a cable, and obtain a plurality of sets of samples from the cable under the plurality of different phase combinations of the transmitter clock and the receiver clock, respectively; and
a processing circuit, arranged to perform channel characteristic analysis according to the plurality of sets of samples provided by the control circuit.

2. The Ethernet PHY transceiver of claim 1, wherein the channel characteristic analysis comprises a time domain reflectometry (TDR) test.

3. The Ethernet PHY transceiver of claim 1, wherein the plurality of sets of samples comprise reflection ratios.

4. The Ethernet PHY transceiver of claim 1, wherein a clock rate of each of the transmitter clock and the receiver clock is equal to a baud rate of the Ethernet PHY transceiver.

5. The Ethernet PHY transceiver of claim 1, wherein the plurality of different phase combinations of the transmitter clock and the receiver clock comprise:
a combination of a first phase of the transmitter clock and a fixed phase of the receiver clock; and
a combination of a second phase of the transmitter clock and the fixed phase of the receiver clock, where the second phase of the transmitter clock is different from the first phase of the transmitter clock.

6. The Ethernet PHY transceiver of claim 1, wherein the plurality of different phase combinations of the transmitter clock and the receiver clock comprise:
a combination of a fixed phase of the transmitter clock and a first phase of the receiver clock; and
a combination of the fixed phase of the transmitter clock and a second phase of the receiver clock, where the second phase of the receiver clock is different from the first phase of the receiver clock.

7. The Ethernet PHY transceiver of claim 1, wherein the plurality of different phase combinations of the transmitter clock and the receiver clock comprise:
a combination of a first phase of the transmitter clock and a first phase of the receiver clock; and
a combination of a second phase of the transmitter clock and a second phase of the receiver clock, where the second phase of the transmitter clock is different from the first phase of the transmitter clock, the second phase of the receiver clock is different from the first phase of the receiver clock, and a difference between the first phase and the second phase of the transmitter clock is different from a difference between the first phase and the second phase of the receiver clock.

8. The Ethernet PHY transceiver of claim 1, wherein the plurality of different phase combinations of the transmitter clock and the receiver clock that are sequentially employed by the control circuit correspond to different phase differences between the transmitter clock and the receiver clock, and the different phase differences are a monotonically-increasing sequence or a monotonically-decreasing sequence.

9. The Ethernet PHY transceiver of claim 1, wherein the plurality of different phase combinations of the transmitter clock and the receiver clock that are sequentially employed by the control circuit correspond to different phase differences between the transmitter clock and the receiver clock, and the different phase differences are not a monotonically-increasing sequence or a monotonically-decreasing sequence.

10. The Ethernet PHY transceiver of claim 9, wherein the processing circuit comprises:
a pseudo random binary sequence generator, arranged to create a pseudo random sequence and output the pseudo random sequence to the control circuit, wherein the different phase differences between the transmitter clock and the receiver clock are set by the control circuit in response to the pseudo random sequence.

11. A channel characteristic analysis method comprising:
sequentially employing a plurality of different phase combinations of a transmitter clock and a receiver clock of an Ethernet physical-layer (PHY) transceiver for transmission and reception of data over a cable;
obtaining a plurality of sets of samples from the cable under the plurality of different phase combinations of the transmitter clock and the receiver clock, respectively; and
performing channel characteristic analysis according to the plurality of sets of samples.

12. The channel characteristic analysis method of claim 11, wherein the channel characteristic analysis comprises a time domain reflectometry (TDR) test.

13. The channel characteristic analysis method of claim 11, wherein the plurality of sets of samples comprise reflection ratios.

14. The channel characteristic analysis method of claim 11, wherein a clock rate of each of the transmitter clock and the receiver clock is equal to a baud rate of the Ethernet PHY transceiver.

15. The channel characteristic analysis method of claim 11, wherein the plurality of different phase combinations of the transmitter clock and the receiver clock comprise:
a combination of a first phase of the transmitter clock and a fixed phase of the receiver clock; and
a combination of a second phase of the transmitter clock and the fixed phase of the receiver clock, where the second phase of the transmitter clock is different from the first phase of the transmitter clock.

16. The channel characteristic analysis method of claim 11, wherein the plurality of different phase combinations of the transmitter clock and the receiver clock comprise:
a combination of a fixed phase of the transmitter clock and a first phase of the receiver clock; and
a combination of the fixed phase of the transmitter clock and a second phase of the receiver clock, where the second phase of the receiver clock is different from the first phase of the receiver clock.

17. The channel characteristic analysis method of claim 11, wherein the plurality of different phase combinations of the transmitter clock and the receiver clock comprise:
a combination of a first phase of the transmitter clock and a first phase of the receiver clock; and
a combination of a second phase of the transmitter clock and a second phase of the receiver clock, where the second phase of the transmitter clock is different from the first phase of the transmitter clock, the second phase of the receiver clock is different from the first phase of the receiver clock, and a difference between the first phase and the second phase of the transmitter clock is different from a difference between the first phase and the second phase of the receiver clock.

18. The channel characteristic analysis method of claim 11, wherein the plurality of different phase combinations of the transmitter clock and the receiver clock that are sequentially employed correspond to different phase differences between the transmitter clock and the receiver clock, and the different phase differences are a monotonically-increasing sequence or a monotonically-decreasing sequence.

19. The channel characteristic analysis method of claim 11, wherein the plurality of different phase combinations of the transmitter clock and the receiver clock that are sequentially employed correspond to different phase differences between the transmitter clock and the receiver clock, and the different phase differences are not a monotonically-increasing sequence or a monotonically-decreasing sequence.

20. The channel characteristic analysis method of claim 19, further comprising:
creating a pseudo random sequence, wherein the different phase differences between the transmitter clock and the receiver clock are set in response to the pseudo random sequence.
